(19) United States
(12) Patent Application Publication
(10) Pub. No.: US 2008/0066863 A1
(43) Pub. Date: Mar. 20, 2008

(54) SUBSTRATE PROCESSING APPARATUS FOR PERFORMING ETCHING PROCESS WITH PHOSPHORIC ACID SOLUTION

(76) Inventors: Hiromi KIYOSE, Kyoto (JP); Teruyuki KOBAYASHI, Kyoto (JP)

Correspondence Address: OSTROLENK FABER GERB & SOFFEN, 1180 AVENUE OF THE AMERICAS, NEW YORK, NY, 100368403, US

(21) Appl. No.: 11/856,764

(22) Filed: Sep. 18, 2007

(30) Foreign Application Priority Data
Sep. 20, 2006 (JP) 2006-253819
Jul. 26, 2007 (JP) 2007-194335

(51) Int. Cl. H01L 21/306

(52) U.S. Cl. 156/345.15

(57) ABSTRACT

A phosphoric acid solution stored in an immersion bath is circulated through a circulation line. Substrates on each of which a silicon oxide film and a silicon nitride film are formed are immersed into the phosphoric acid solution in the immersion bath, to proceed a process of selectively etching the silicon nitride film. A recovery line draws part of the phosphoric acid solution circulating through the circulation line, and collects and discharges siloxane with a recovery device to recover the phosphoric acid solution. A control part controls a flow rate regulating valve on the basis of measurement results of an outlet concentration meter and an inlet concentration meter, to regulate the flow rate of the phosphoric acid solution to be circulated to the immersion bath so that the concentration of siloxane contained in the phosphoric acid solution stored in the immersion bath should be constant.

### BACKGROUND OF THE INVENTION

1. Field of the Invention

The present invention relates to a substrate processing apparatus for performing an etching process, specifically by immersing a substrate, such as a semiconductor wafer, a glass substrate for liquid crystal display, a glass substrate for photomask or a substrate for optical disk, on which a silicon oxide film and a silicon nitride film are formed, in a phosphoric acid solution to selectively etch the silicon nitride film.

2. Description of the Background Art

An etching process is a very important process step for pattern formation in manufacturing semiconductor devices. In recent years, with high performance and high integration of semiconductor devices, required is an etching process on a substrate on which a silicon nitride film (Si₃N₄ film) and a silicon oxide film (SiO₂ film) are formed, to selectively etch the silicon nitride film so that the silicon oxide film should be left on the substrate. As a method of selectively etching the silicon nitride film, an etching process using a phosphoric acid solution (H₃PO₄+H₂O) of high temperature (about 150° C.) as an etching solution is disclosed in Japanese Patent Application Laid Open Gazette No. 2003-224106. Specifically, a plurality of substrates on each of which a silicon nitride film and a silicon oxide film are formed are immersed in a processing bath in which a phosphoric acid solution of high temperature is stored, to selectively etch the silicon nitride film.

When a process of etching a silicon nitride film is performed by using a phosphoric acid solution, usually, siloxane is generated. “Siloxane” is a generic name for a family of organic or inorganic compounds whose main ingredients are silicon (Si) and oxygen (O). Siloxane generated in an etching process accumulates in an etching solution as an extraneous matter. As siloxane accumulates, the etching speed (rate) of silicon nitride film becomes lower, and when the concentration of siloxane in an etching solution exceeds a certain concentration, the siloxane adheres to the substrate or the processing bath or clogs a filter for circulating the etching solution. On the other hand, when the concentration of siloxane in an etching solution is too low, the etching speed of silicon oxide film becomes higher and the etching selection ratio of silicon nitride film becomes lower.

For this reason, it is necessary to maintain constant concentration of siloxane in the etching solution in the processing bath, and Japanese Patent Application Laid Open Gazette No. 2003-224106 discloses a technique to maintain constant concentration of siloxane in an etching solution by drawing part of the etching solution from a circulation line of the etching solution to forcedly precipitate siloxane in the etching solution and collect it.

In the technique disclosed in Japanese Patent Application Laid Open Gazette No. 2003-224106, however, the amount of siloxane to be collected and discharged per unit of time is always constant. On the other hand, the amount of siloxane accumulating in the etching solution varies with the frequency of processing on substrates, the number of substrates to be processed, the area ratio of silicon nitride film on a substrate or the like at any time, and is not always constant. As a result, the concentration of siloxane in the etching solution stored in the processing bath does not become constant and this causes variation in etching rate of silicon nitride film.

### SUMMARY OF THE INVENTION

The present invention is intended for a substrate processing apparatus for performing an etching process by immersing a substrate on which a silicon oxide film and a silicon nitride film are formed into a phosphoric acid solution to etch the silicon nitride film.

According to the present invention, the substrate processing apparatus comprises an immersion bath for storing a phosphoric acid solution in which the substrate is immersed to etch a silicon nitride film, a circulation line for circulating a phosphoric acid solution discharged from the immersion bath into the immersion bath again, a recovery line branching off from the circulation line, for circulating part of a phosphoric acid solution flowing in the circulation line into the immersion bath through a path separately from the circulation line, a recovery mechanism inserted in the path of the recovery line, for collecting siloxane contained in a phosphoric acid solution flowing in the recovery line to recover the phosphoric acid solution, a first concentration meter inserted in a path of the circulation line, for measuring the concentration of siloxane contained in the phosphoric acid solution discharged from the immersion bath, a second concentration meter inserted in the path of the recovery line on the downstream side of the recovery mechanism, for measuring the concentration of siloxane contained in the phosphoric acid solution recovered by the recovery mechanism, a flow rate regulating part inserted in the path of the recovery line on the downstream side of the second concentration meter, for regulating the flow rate of the phosphoric acid solution flowing in the recovery line, and a control part for controlling the flow rate regulating part to regulate the flow rate of a phosphoric acid solution to be circulated from the recovery line to the immersion bath so that the concentration of siloxane contained in the phosphoric acid solution stored in the immersion bath should be almost constant on the basis of measurement results of the first concentration meter and the second concentration meter.

It is thereby possible to maintain constant etching rate of the silicon nitride film formed on the substrate by making the concentration of siloxane constant, which is contained in the phosphoric acid solution stored in the immersion bath, regardless of the frequency of processing on substrate, the area ratio of the silicon nitride film or the like.

According to one aspect of the present invention, the substrate processing apparatus comprises an immersion bath for storing a phosphoric acid solution in which the substrate is immersed to etch a silicon nitride film, a circulation line for circulating a phosphoric acid solution discharged from the immersion bath into the immersion bath again, a recovery line branching off from the circulation line, for circulating part of a phosphoric acid solution flowing in the circulation line into the immersion bath through a path separately from the circulation line, a recovery mechanism inserted in the path of the recovery line, for collecting siloxane contained in a phosphoric acid solution flowing in the recovery line to recover the phosphoric acid solution, a first concentration meter inserted in a path of the circulation line, for measuring the concentration of siloxane contained in the phosphoric acid solution discharged from the immersion bath, a flow rate regulating part for regulating the flow rate of the phosphoric acid solution flowing in the recovery line, and a control part for controlling the flow rate regulating part to increase the flow rate of a phosphoric acid solution to be circulated from the recovery line to the immersion bath when the concentration of siloxane measured by the first concentration meter exceeds a set value which is determined in advance.

Preferably, the substrate processing apparatus further comprises a second concentration meter inserted in the path of the recovery line on the downstream side of the recovery mechanism, for measuring the concentration of siloxane contained in the phosphoric acid solution recovered by the recovery mechanism, and the control part controls the flow rate regulating part to regulate the flow rate of the phosphoric acid solution to be circulated from the recovery line to the immersion bath in accordance with the concentration of siloxane measured by the second concentration meter.

It is thereby possible to maintain constant concentration of siloxane contained in the phosphoric acid solution stored in the immersion bath with higher accuracy.

Therefore, it is an object of the present invention to provide a substrate processing apparatus capable of maintaining constant etching rate of a silicon nitride film formed on a substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing an overall schematic construction of a substrate processing apparatus in accordance with a first preferred embodiment of the present invention;

FIG. 2 is a view showing an overall schematic construction of a substrate processing apparatus in accordance with a second preferred embodiment of the present invention; and

FIG. 3 is a graph showing saturation concentration of siloxane in a phosphoric acid solution.

### DESCRIPTION OF THE PREFERRED EMBODIMENTS

Hereinafter, preferred embodiments of the present invention will be discussed in detail with reference to figures.

### 1. The First Preferred Embodiment

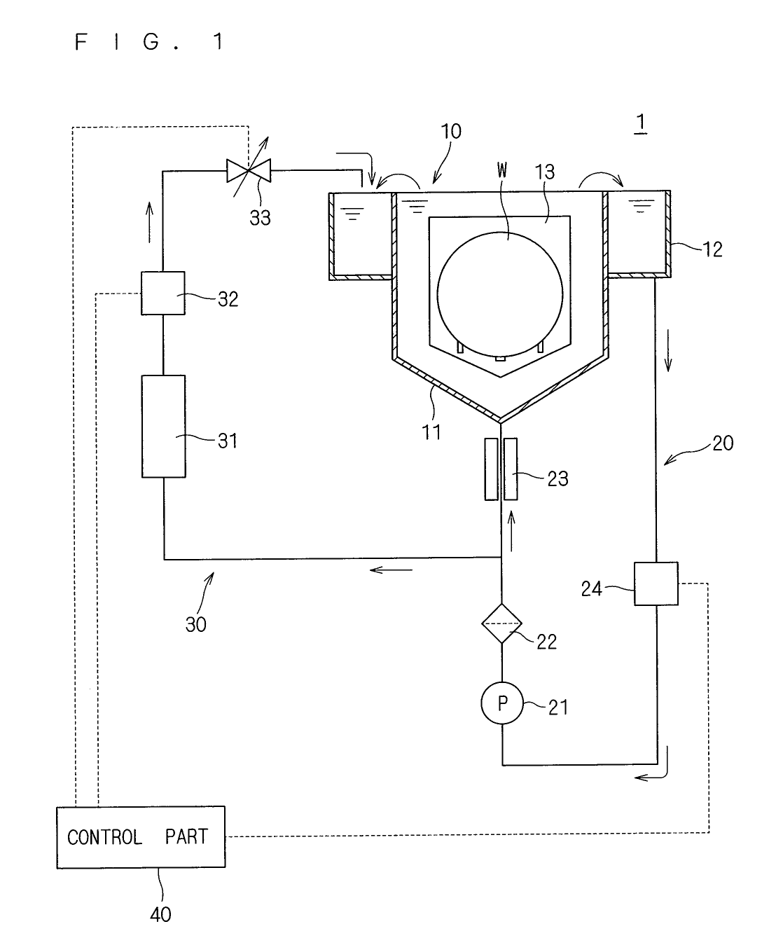

FIG. 1 is a view showing an overall schematic construction of a substrate processing apparatus in accordance with the first preferred embodiment of the present invention. This substrate processing apparatus 1 is a wet etching apparatus for performing an etching process, specifically by immersing a substrate W on which a silicon oxide film and a silicon nitride film are formed, in a phosphoric acid solution to selectively etch the silicon nitride film. The substrate processing apparatus 1 comprises an immersion bath 10 for storing a phosphoric acid solution to perform an etching process, a circulation line 20 for circulating the phosphoric acid solution to the immersion bath 10 and a recovery line 30 for recovering the phosphoric acid solution.

The immersion bath 10 has a double-bath structure consisting of an inside bath 11 for storing the phosphoric acid solution as an etching solution and immersing a substrate W in the phosphoric acid solution and an outside bath 12 for collecting an etching solution which overflows from an upper portion of the inside bath 11. The inside bath 11 is a box-like member having a rectangular shape in a plan view, which is formed of quartz or fluorocarbon resin having excellent corrosion resistance against the etching solution. The outside bath 12 is formed of the same material as that of the inside bath 11 and so provided as to surround the outer peripheral upper end portion of the inside bath 11.

Further, a lifter 13 is provided to immerse the substrate W into the etching solution stored in the immersion bath 10. The lifter 13 collectively holds a plurality of (e.g., fifty) substrates W arranged uprightly (with the normal of a main surface of the substrate along the horizontal direction) in parallel to one another, with three holding rods. The lifter 13 is so provided as to be moved in vertical direction by a not-shown elevation mechanism, and moves the substrates W (lot) held thereby between a processing position (the position of FIG. 1) where the substrates W are immersed into the etching solution in the inside bath 11 and a passing position where the substrates W are drawn out from the etching solution.

The circulation line 20 is a piping path to filter and heat the phosphoric acid solution discharged from the immersion bath 10 and circulate it to the immersion bath 10 again under pressure, and specifically, formed by connecting the bottom portion of the outside bath 12 to the bottom portion of the inside bath 11 with a duct. In the path of the circulation line 20, a circulation pump 21 and a filter 22 are provided from the upstream side. The circulation pump 21 sends the phosphoric acid solution drawn out from the outside bath 12 through the circulation line 20 to the inside bath 11 under pressure. The filter 22 is provided to clear extraneous matters from the phosphoric acid solution flowing in the circulation line 20.

The circulation line 20 is further provided with a heater 23 on the downstream side of the filter 22. The heater 23 is provided closest to the inside bath 11 in the circulation line 20, to heat the phosphoric acid solution flowing in the circulation line 20 to a predetermined processing temperature (150° C. in this preferred embodiment) again. The immersion bath 10 is further provided with a not-shown heater and heats the phosphoric acid solution stored in the immersion bath 10 to keep the predetermined processing temperature.

The recovery line 30 is a piping path to draw and recover part of the phosphoric acid solution flowing in the circulation line 20 and circulate the recovered solution to the immersion bath 10 separately from the circulation line 20. “Recovery” of the phosphoric acid solution is to collect the siloxane contained in the phosphoric acid solution, to reduce the concentration of siloxane. The recovery line 30 branches off at a point in the circulation line 20 on the downstream side of the filter 22 (closer to the inside bath 11) and circulates the recovered phosphoric acid solution to the outside bath 12 of the immersion bath 10. Though the recovery line 30 may branch off at any point in the circulation line 20, it is preferable that the recovery line 30 should branch off on the downstream side of the filter 22, like in this preferred embodiment, in order to draw the phosphoric acid solution after being cleared of the extraneous matters.

In the path of the recovery line 30, a recovery device 31 is inserted to collect the siloxane contained in the phosphoric acid solution and recover the phosphoric acid solution. The recovery device 31 of this preferred embodiment forcedly precipitates the siloxane contained in the phosphoric acid solution flowing in the recovery line 30 to collect and remove it. As the recovery device 31, a variety of well-known devices may be adopted only if they can collect the siloxane contained in the phosphoric acid solution, and for example, a collecting device disclosed in Japanese Patent Application Laid Open Gazette No. 2003-224106 may be used.

Further, an outlet concentration meter 24 (the first concentration meter) and an inlet concentration meter 32 (the second concentration meter) are inserted in the paths of the circulation line 20 and the recovery line 30, respectively. The outlet concentration meter 24 is provided on the upstream side of the circulation pump 21 in the circulation line 20 (closer to the outside bath 12) to measure the concentration of siloxane contained in the phosphoric acid solution discharged from the outside bath 12 of the immersion bath 10. On the other hand, the inlet concentration meter 32 is provided on the downstream side of the recovery device 31 in the recovery line 30 (closer to the outside bath 12) to measure the concentration of siloxane contained in the phosphoric acid solution recovered by the recovery device 31. A flow rate regulating valve 33 is further inserted in the path of the recovery line 30 on the downstream side of the inlet concentration meter 32 (closer to the outside bath 12). The flow rate regulating valve 33 is a valve to regulate the flow rate of the phosphoric acid solution flowing in the recovery line 30.

The substrate processing apparatus 1 is further provided with a control part 40 to control the entire apparatus. The control part 40 has a constitution of general computer system as hardware. Specifically, the control part 40 comprises a CPU for performing various computations, a ROM for storing a basic program, a RAM which is a readable and writable memory for storing various information, a magnetic disk or the like for storing control applications or data. In the first preferred embodiment, the CPU of the control part 40 performs a predetermined software and the control part 40 thereby controls the flow rate regulating valve 33 on the basis of the measurement results of the outlet concentration meter 24 and the inlet concentration meter 32. The control part 40 also controls other operation parts in the substrate processing apparatus 1, such as the circulation pump 21, the heater 23 and the elevation mechanism for the lifter 13.

Next, discussion will be made on an operation of the substrate processing apparatus 1 having the above constitution. First, the circulation pump 21 sends the phosphoric acid solution at a constant flow rate under pressure at all times regardless of whether substrates W are immersed in the phosphoric acid solution stored in the immersion bath 10 or not. The phosphoric acid solution circulated to the immersion bath 10 through the circulation line 20 is supplied from the bottom portion of the inside bath 11. This causes an upflow of the phosphoric acid solution towards the upper portion from the bottom portion inside the inside bath 11. The phosphoric acid solution supplied from the bottom portion then overflows from the upper end portion of the inside bath 11 to flow into the outside bath 12. The phosphoric acid solution flowing into the outside bath 12, going through the circulation line 20, is then collected and circulated to the immersion bath 10 again under pressure by the circulation pump 21. Thus, the circulation process is continuously performed. In the circulation through the circulation line 20, the extraneous matters contained in the phosphoric acid solution are cleared off by the filter 22. The circulating phosphoric acid solution is heated again by the heater 23 to the predetermined processing temperature.

While the circulation process for the phosphoric acid solution is performed through the circulation line 20, the lifter 13 which receives a plurality of substrates W at the passing position goes down to the processing position to immerse the substrates W into the phosphoric acid solution stored in the inside bath 11. This causes an etching process, to selectively etch the silicon nitride film out of the silicon oxide film and the silicon nitride film which are formed on the substrates W. Thus, the silicon nitride film is gradually removed. After a predetermined time period, when the etching process is finished, the lifter 13 goes up again to the passing position to draw the substrates W out from the etching solution.

As the process of etching the silicon nitride film proceeds, siloxane accumulates in the phosphoric acid solution. When the siloxane excessively accumulates, the etching speed (rate) of the silicon nitride film slows and this causes problems such as contamination of the substrates W and the immersion bath 10 and clogging of the filter 22, as discussed earlier. Therefore, in the first preferred embodiment, the recovery line 30 is provided in order to collect excessive amounts of siloxane and recover the phosphoric acid solution.

The recovery line 30 draws part of the phosphoric acid solution flowing in the circulation line 20 from the midpoint of the circulation line 20. Then, the recovery line 30 uses the recovery device 31 to collect and discharge the siloxane from the drawn solution to recover the phosphoric acid solution, and circulates the recovered phosphoric acid solution whose concentration of the siloxane is lowered to the immersion bath 10. Since the phosphoric acid solution whose concentration of the siloxane is low thereby flows into the immersion bath 10 from the recovery line 30, it is possible to prevent the concentration of siloxane in the phosphoric acid solution stored in the immersion bath 10 from becoming too high. The reason why the recovered phosphoric acid solution is supplied to the outside bath 12 of the immersion bath 10 from the recovery line 30 is that variation and distribution in the concentration of siloxane inside the inside bath 11 become more stable when the phosphoric acid solution with low concentration of siloxane is supplied to the outside bath 12, once going through the circulation line 20, and then supplied to the inside bath 11 than when the phosphoric acid solution with low concentration of siloxane is directly supplied to the inside bath 11.

In the first preferred embodiment, the circulation line 20 is further provided with the outlet concentration meter 24 and the recovery line 30 is further provided with the inlet concentration meter 32 and the flow rate regulating valve 33, and the control part 40 controls the flow rate regulating valve 33 on the basis of the measurement results of the outlet concentration meter 24 and the inlet concentration meter 32 to regulate the flow rate of the phosphoric acid solution to be circulated to the immersion bath 10 from the recovery line 30. At that time, the control part 40 regulates the flow rate of the phosphoric acid solution with low concentration of siloxane to be circulated to the immersion bath 10 from the recovery line 30 so that the concentration of siloxane contained in the phosphoric acid solution stored in the immersion bath 10 should become constant.

The outlet concentration meter 24 is provided in the circulation line 20 to measure the concentration of siloxane contained in the phosphoric acid solution discharged from the immersion bath 10. In other words, the outlet concentration meter 24 measures the concentration of siloxane on the outlet side of the immersion bath 10, and the concentration of siloxane measured by the outlet concentration meter 24 is almost equal to the concentration of siloxane contained in the phosphoric acid solution stored in the immersion bath 10.

On the other hand, the inlet concentration meter 32 is provided in the recovery line 30 to measure the concentration of siloxane contained in the phosphoric acid solution to be recovered by the recovery device 31 and circulated to the immersion bath 10. In other words, the inlet concentration meter 32 measures the concentration of siloxane on the inlet side of the immersion bath 10. Since the amount of phosphoric acid solution stored in the immersion bath 10 is constant, if the respective concentrations of siloxane on the outlet and inlet sides of the immersion bath 10 can be measured, it is possible to calculate such inflow from the recovery line 30 that the concentration of siloxane contained in the phosphoric acid solution stored in the immersion bath 10 should become constant. The control part 40 detects the respective concentrations of siloxane on the outlet and inlet sides of the immersion bath 10 from the measurement results of the outlet concentration meter 24 and the inlet concentration meter 32, calculates such flow rate of the phosphoric acid solution from the recovery line 30 that the concentration of siloxane contained in the phosphoric acid solution stored in the immersion bath 10 should become constant on the basis of the detected concentrations and controls the flow rate regulating valve 33 so that the phosphoric acid solution with low concentration of siloxane should be circulated from the recovery line 30 to the immersion bath 10 at the calculated flow rate.

Specifically, while the etching process is performed on the substrates W in the immersion bath 10, the siloxane continues to accumulate in the phosphoric acid solution and the concentration of siloxane contained in the phosphoric acid solution stored in the immersion bath 10 tends to increase. When the concentration of siloxane contained in the phosphoric acid solution increases, the etching speed (rate) of the silicon nitride film becomes lower and this sometimes causes contamination of the substrates W and clogging of the filter 22. For this reason, when it is found in the measurement result of the outlet concentration meter 24 that the concentration of siloxane becomes higher than a predetermined value, the control part 40 controls the flow rate regulating valve 33 to increase the flow rate of the phosphoric acid solution with lowered concentration of siloxane to be circulated from the recovery line 30 to the immersion bath 10, thereby suppressing an increase in concentration of siloxane contained in the phosphoric acid solution stored in the immersion bath 10.

On the other hand, while the etching process is not performed on the substrates W, the concentration of siloxane contained in the phosphoric acid solution stored in the immersion bath 10 does not increase since no new siloxane is generated. In such a condition, if the siloxane going through the recovery line 30 continues to be collected and discharged, the concentration of siloxane contained in the phosphoric acid solution stored in the immersion bath 10 decreases. When the concentration of siloxane contained in the phosphoric acid solution becomes too low, the etching selection ratio of the silicon nitride film is lowered. For this reason, when it is found in the measurement result of the outlet concentration meter 24 that the concentration of siloxane tends to be lower than the predetermined value, the control part 40 controls the flow rate regulating valve 33 to decrease the flow rate of the phosphoric acid solution with lowered concentration of siloxane to be circulated from the recovery line 30 to the immersion bath 10, thereby preventing a decrease in concentration of siloxane contained in the phosphoric acid solution stored in the immersion bath 10. Even if the flow rate of the phosphoric acid solution to be circulated through the recovery line 30 to the immersion bath 10 increases or decreases, the increase or decrease in the amount of flow is compensated with the amount of flow in the circulation line 20 since the circulation pump 21 circulates the phosphoric acid solution under pressure at a constant flow rate at all times.

Thus, even if the amount of siloxane to be generated varies with the frequency of processing on substrates W, the number of substrates W to be processed, the area ratio of the silicon nitride film on a substrate W or the like, it is possible to maintain constant etching rate of the silicon nitride film formed on the substrate W in the etching process since the concentration of siloxane contained in the phosphoric acid solution stored in the immersion bath 10 can be kept constant at all times. As a result, it becomes possible to prevent clogging of the filter 22 and suppress unnecessary etching of the silicon oxide film.

### 2. The Second Preferred Embodiment

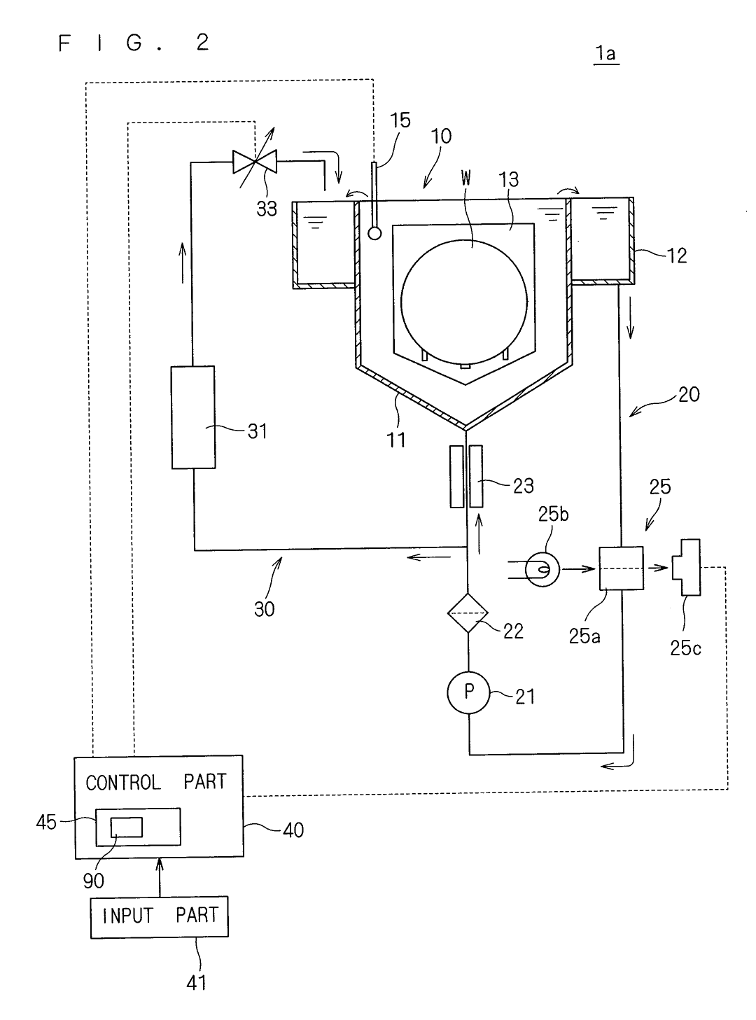

Next, discussion will be made on the second preferred embodiment of the present invention. FIG. 2 is a view showing an overall schematic construction of a substrate processing apparatus in accordance with the second preferred embodiment of the present invention. In FIG. 2, constituent elements identical to those of the first preferred embodiment are represented by the same reference signs in FIG. 1. The substrate processing apparatus 1a of the second preferred embodiment is also a wet etching apparatus for performing an etching process, specifically by immersing a substrate W on which a silicon oxide film and a silicon nitride film are formed, in a phosphoric acid solution to selectively etch the silicon nitride film. The substrate processing apparatus 1a also comprises the immersion bath 10 for storing a phosphoric acid solution to perform an etching process, the circulation line 20 for circulating the phosphoric acid solution to the immersion bath 10 and the recovery line 30 for recovering the phosphoric acid solution.

The respective constitutions of the immersion bath 10 and the circulation line 20 are almost the same as those in the first preferred embodiment. Also in the second preferred embodiment, in the path of the circulation line 20, an outlet concentration meter 25 (the first concentration meter) is inserted. The outlet concentration meter 25 is provided on the upstream side of the circulation pump 21 (closer to the outside bath 12) in the circulation line 20 and measures the concentration of siloxane contained in the phosphoric acid solution discharged from the outside bath 12 of the immersion bath 10.

The outlet concentration meter 25 of the second preferred embodiment is a concentration meter for measuring the concentration of siloxane in a solution by measuring the absorbance of a specific wavelength, and comprises a flow cell 25a, a light source 25b such as a halogen lamp, and a photodetector 25c for detecting transmission light. The flow cell 25a includes an optically transparent flat duct in which the phosphoric acid solution flows. Light is emitted from the light source 25b to one-surface side of the flow cell 25a, going through the flow cell 25a in which the phosphoric acid solution flows, and is detected by the photodetector 25c. A concentration signal detected by the photodetector 25c is transmitted to the control part 40.

The outlet concentration meter 25 can measure whether the siloxane is precipitated or not by measuring the intensity of the entire transmission light as well as the concentration of siloxane by measuring the absorbance of a specific wavelength. If the siloxane is precipitated, the concentration of siloxane contained in the phosphoric acid solution exceeds the saturation concentration. Further, as the outlet concentration meter 24 and the inlet concentration meter 32 in the first preferred embodiment, the same type of concentration meter as in the second preferred embodiment, which measures the absorbance, may be used.

In the path of the recovery line 30, the recovery device 31 for collecting the siloxane contained in the phosphoric acid solution and recovering the phosphoric acid solution and the flow rate regulating valve 33 are inserted. The flow rate regulating valve 33 is a valve to regulate the flow rate of the phosphoric acid solution flowing in the recovery line 30. In the second preferred embodiment, however, the inlet concentration meter for measuring the concentration of siloxane contained in the recovered phosphoric acid solution is not provided.

The control part 40 is provided with an input part 41 for receiving an input from the outside. The input part 41 is, e.g., a touch panel, and an operator can inputs various commands and parameters from this input part 41. The commands and parameters received by the input part 41 are transmitted to the control part 40.

In the second preferred embodiment, a temperature sensor 15 is further provided to measure the temperature of the phosphoric acid solution stored in the immersion bath 10. A signal indicating the temperature of the phosphoric acid solution measured by the temperature sensor 15 is transmitted to the control part 40. The other constituent elements in the substrate processing apparatus 1a of the second preferred embodiment are the same as those in the first preferred embodiment and therefore represented by the same reference signs, and detailed description thereof will be omitted.

Next, discussion will be made on an operation of the substrate processing apparatus 1a of the second preferred embodiment. Details of the etching process in the substrate processing apparatus 1a are the same as those in the first preferred embodiment. Specifically, while the circulation process for the phosphoric acid solution in the circulation line 20 is performed, the substrates W are immersed in the phosphoric acid solution stored in the immersion bath 10. Thus, the etching process proceeds, to selectively etch the silicon nitride film out of the silicon oxide film and the silicon nitride film which are formed on the substrates W. As the process of etching the silicon nitride film proceeds, the siloxane accumulates in the phosphoric acid solution.

For this reason, also in the second preferred embodiment, the recovery line 30 is provided in order to collect excessive amounts of siloxane and recover the phosphoric acid solution. Specifically, the recovery line 30 draws part of the phosphoric acid solution circulating in the circulation line 20 from the midpoint of the circulation line 20. Then, the recovery line 30 uses the recovery device 31 to collect and discharge the siloxane from the drawn solution to recover the phosphoric acid solution, and circulates the recovered phosphoric acid solution whose concentration of the siloxane is lowered to the immersion bath 10.

In the second preferred embodiment, a target value for the concentration of siloxane is set in the control part 40 in advance. Specifically, the operator inputs the target value (set value) for the concentration of siloxane from the input part 41. In this case, a value relative to the saturation concentration of siloxane is inputted from the input part 41 as the set value. As discussed earlier, when the concentration of siloxane contained in the phosphoric acid solution becomes too low, the etching speed (rate) of the silicon oxide film becomes higher and the etching selection ratio of the silicon nitride film is lowered. Conversely, when the concentration of siloxane becomes too high, this causes problems such as clogging of the filter 22, but such problems are caused only when the concentration of siloxane exceeds the saturation concentration and the siloxane is precipitated. For this reason, in the second preferred embodiment, the target value is set to be not lower than 50% of the saturation concentration of siloxane and not higher than 100% thereof. Within this range, there is no possibility that the etching selection ratio of the silicon nitride film should be lowered or the filter 22 should be clogged. The set value received by the input part 41 is stored in a storage part 45 in the control part 40. The storage part 45 is, e.g., a memory of the control part 40.

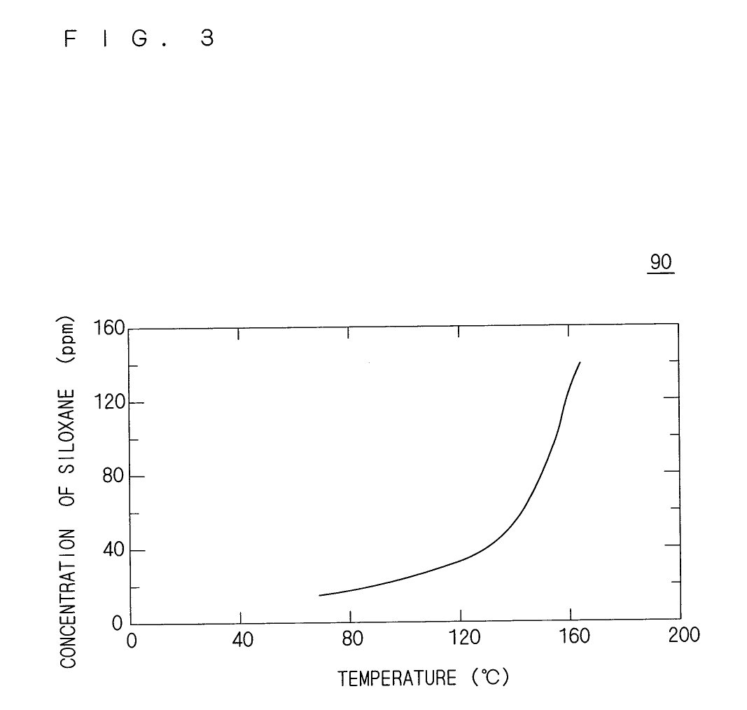

On the other hand, the storage part 45 stores a look-up table 90 in advance, which indicates the saturation concentration of siloxane contained in the phosphoric acid solution. FIG. 3 is a graph showing saturation concentration of siloxane in a phosphoric acid solution. In FIG. 3, the horizontal axis represents the temperature of phosphoric acid solution and the vertical axis represents the concentration of siloxane. As the temperature of the phosphoric acid solution becomes higher, the saturation concentration of siloxane also becomes higher.

It is assumed, for example, that a set value of 80% is inputted under the condition where a phosphoric acid solution of 160° C. is stored in the immersion bath 10 to perform an etching process. In this case, the control part 40 recognizes, from the look-up table 90 of FIG. 3 which is stored in the storage part 45, that the saturation concentration of siloxane in the phosphoric acid solution of 160° C. is 120 ppm. Then, the control part 40 sets 96 ppm which is 80% of the saturation concentration, as a concentration threshold value. This concentration threshold value is obtained by concentration conversion of the inputted set value in accordance with the processing temperature of the phosphoric acid solution.

While the etching process is performed on the substrates W in the immersion bath 10, the siloxane continues to accumulate in the phosphoric acid solution and the concentration of siloxane contained in the phosphoric acid solution stored in the immersion bath 10 increases. When the concentration of siloxane measured by the outlet concentration meter 25 exceeds the threshold value (96 ppm in the above case) which is obtained by concentration conversion of the set value, the control part 40 controls the flow rate regulating valve 33 to increase the flow rate of the phosphoric acid solution to be circulated from the recovery line 30 to the immersion bath 10. The flow rate of the phosphoric acid solution with low concentration of siloxane (about 20 ppm) from the recovery line 30 to the immersion bath 10 thereby increases, and the concentration of siloxane contained in the phosphoric acid solution stored in the immersion bath 10 decreases.

On the other hand, when the concentration of siloxane measured by the outlet concentration meter 25 does not reach the above threshold value, the control part 40 controls the flow rate regulating valve 33 to decrease the flow rate of the phosphoric acid solution to be circulated from the recovery line 30 to the immersion bath 10. The flow rate of the phosphoric acid solution with low concentration of siloxane from the recovery line 30 to the immersion bath 10 thereby decreases, and the concentration of siloxane contained in the phosphoric acid solution stored in the immersion bath 10 increases as the etching process proceeds. Thus, the concentration of siloxane contained in the phosphoric acid solution stored in the immersion bath 10 is kept almost constant (at the set value), and as a result, it is possible to maintain constant etching rate of the silicon nitride film formed on the substrate W. When the concentration of siloxane measured by the outlet concentration meter 25 is equal to the above threshold value, the flow rate of the phosphoric acid solution to be circulated from the recovery line 30 to the immersion bath 10 may be increased or decreased.

The outlet concentration meter 25 of the second preferred embodiment can also measure whether the siloxane in the phosphoric acid solution is precipitated or not. For this reason, even if a set value of 100% is inputted, it is possible to detect that the concentration of siloxane contained in the phosphoric acid solution should exceed the set value. In other words, if a set value of 100% is inputted, when precipitation of siloxane is detected by the outlet concentration meter 25, the control part 40 controls the flow rate regulating valve 33 to increase the flow rate of the phosphoric acid solution to be circulated from the recovery line 30 to the immersion bath 10.

### 3. Variations

Though the preferred embodiments of the present invention have been discussed above, besides the above preferred embodiments, numerous modifications and variations can be devised without departing from the scope of the invention. For example, in the substrate processing apparatus 1a of the second preferred embodiment, the inlet concentration meter 32 (the second concentration meter) may be inserted on the downstream side of the recovery device 31 in the recovery line 30, like in the first preferred embodiment. Though the concentration of siloxane contained in the phosphoric acid solution recovered by the recovery device 31 is almost stable, the concentration of siloxane contained in the recovered phosphoric acid solution flowing into the immersion bath 10 is measured by the inlet concentration meter and the control part 40 makes a fine adjustment to the flow rate of the phosphoric acid solution to be circulated from the recovery line 30 to the immersion bath 10 on the basis of the measurement result. Specifically, if the concentration of siloxane contained in the phosphoric acid solution recovered by the recovery device 31 is lower than a standard value, the control part 40 decreases the flow rate of the phosphoric acid solution to be circulated from the recovery line 30 to the immersion bath 10, and if the concentration of siloxane is higher than the standard value, the control part 40 increases the flow rate of the phosphoric acid solution to be circulated from the recovery line 30 to the immersion bath 10. Thus, it becomes possible to maintain the concentration of siloxane contained in the phosphoric acid solution stored in the immersion bath 10 at the set value with higher accuracy. Further, as the inlet concentration meter, the same type of concentration meter as the outlet concentration meter 25, which measures the absorbance, may be used.

While a value relative to the saturation concentration of siloxane is inputted as the set value and the value is converted into concentration in accordance with the processing temperature of the phosphoric acid solution in the second preferred embodiment, a concentration value, instead, may be directly inputted from the input part 41 as the set value.

Further, in the above preferred embodiments, the recovery line 30 may circulate the recovered phosphoric acid solution to the inside bath 11. The outside bath 12 is not indispensable, and there may be another constitution where both ends of the pipe of the circulation line 20 communicate with the inside bath 11 and the phosphoric acid solution inside the inside bath 11 is circulated by the circulation line 20. While the lifter 13 directly holds a plurality of substrates W in the above preferred embodiments, the lifter 13 may hold a carrier accommodating a plurality of substrates W and move up and down.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus for performing an etching process by immersing a substrate on which a silicon oxide film and a silicon nitride film are formed into a phosphoric acid solution to etch the silicon nitride film, comprising:
an immersion bath for storing a phosphoric acid solution in which said substrate is immersed to etch a silicon nitride film;
a circulation line for circulating a phosphoric acid solution discharged from said immersion bath into said immersion bath again;
a recovery line branching off from said circulation line, for circulating part of a phosphoric acid solution flowing in said circulation line into said immersion bath through a path separately from said circulation line;
a recovery mechanism inserted in the path of said recovery line, for collecting siloxane contained in a phosphoric acid solution flowing in said recovery line to recover the phosphoric acid solution;
a first concentration meter inserted in a path of said circulation line, for measuring the concentration of siloxane contained in the phosphoric acid solution discharged from said immersion bath;
a second concentration meter inserted in the path of said recovery line on the downstream side of said recovery mechanism, for measuring the concentration of siloxane contained in the phosphoric acid solution recovered by said recovery mechanism;
a flow rate regulating part inserted in the path of said recovery line on the downstream side of said second concentration meter, for regulating the flow rate of the phosphoric acid solution flowing in said recovery line; and
a control part for controlling said flow rate regulating part to regulate the flow rate of a phosphoric acid solution to be circulated from said recovery line to said immersion bath so that the concentration of siloxane contained in the phosphoric acid solution stored in said immersion bath should be almost constant on the basis of measurement results of said first concentration meter and said second concentration meter.

2. A substrate processing apparatus for performing an etching process by immersing a substrate on which a silicon oxide film and a silicon nitride film are formed into a phosphoric acid solution to etch the silicon nitride film, comprising:
an immersion bath for storing a phosphoric acid solution in which said substrate is immersed to etch a silicon nitride film;
a circulation line for circulating a phosphoric acid solution discharged from said immersion bath into said immersion bath again;
a recovery line branching off from said circulation line, for circulating part of a phosphoric acid solution flowing in said circulation line into said immersion bath through a path separately from said circulation line;
a recovery mechanism inserted in the path of said recovery line, for collecting siloxane contained in a phosphoric acid solution flowing in said recovery line to recover the phosphoric acid solution;
a first concentration meter inserted in a path of said circulation line, for measuring the concentration of siloxane contained in the phosphoric acid solution discharged from said immersion bath;
a flow rate regulating part for regulating the flow rate of the phosphoric acid solution flowing in said recovery line; and
a control part for controlling said flow rate regulating part to increase the flow rate of a phosphoric acid solution to be circulated from said recovery line to said immersion bath when the concentration of siloxane measured by said first concentration meter exceeds a set value which is determined in advance.

3. The substrate processing apparatus according to claim 2, wherein
said control part controls said flow rate regulating part to decrease the flow rate of the phosphoric acid solution to be circulated from said recovery line to said immersion bath when the concentration of siloxane measured by said first concentration meter does not reach said set value.

4. The substrate processing apparatus according to claim 3, further comprising
a temperature measuring part for measuring the temperature of the phosphoric acid solution stored in said immersion bath,
wherein said set value is determined as a value relative to the saturation concentration of siloxane at the temperature of phosphoric acid solution measured by said temperature measuring part.

5. The substrate processing apparatus according to claim 4, wherein
said set value is not lower than 50% of said saturation concentration of siloxane and not higher than 100% thereof.

6. The substrate processing apparatus according to claim 2, further comprising
an input receiving part for receiving an input of said set value.

7. The substrate processing apparatus according to claim 2, further comprising
a second concentration meter inserted in the path of said recovery line on the downstream side of said recovery mechanism, for measuring the concentration of siloxane contained in the phosphoric acid solution recovered by said recovery mechanism,
wherein said control part controls said flow rate regulating part to regulate the flow rate of the phosphoric acid solution to be circulated from said recovery line to said immersion bath in accordance with the concentration of siloxane measured by said second concentration meter.
